(19) United States
(12) Patent Application Publication
(10) Pub. No.: US 2014/0044502 A1
(43) Pub. Date: Feb. 13, 2014

(54) VACUUM PROCESSING APPARATUS AND METHOD OF OPERATING THE SAME

(71) Applicants: Takashi UEMURA, Kudamatsu (JP); Hideaki Kondo, Kudamatsu (JP); Masakazu Isozaki, Shunan (JP); Takahiro Shimomura, Kudamatsu (JP)

(72) Inventors: Takashi UEMURA, Kudamatsu (JP); Hideaki Kondo, Kudamatsu (JP); Masakazu Isozaki, Shunan (JP); Takahiro Shimomura, Kudamatsu (JP)

(21) Appl. No.: 13/606,109

(22) Filed: Sep. 7, 2012

(30) Foreign Application Priority Data
Aug. 7, 2012 (JP) 2012-174524

(51) Int. Cl. H01L 21/677

(52) U.S. Cl. 414/217; 414/805

(57) ABSTRACT

In a vacuum processing apparatus including a plurality of vacuum transfer vessels arranged back and forth at the back of a lock chamber, an intermediate chamber arranged between them and capable of accommodating wafers, and processing units connected to respective vacuum transfer vessels, a wafer processed in a pre-processing vessel out of the processing units connected to the respective vacuum transfer vessels is transferred to a post-processing vessel connected to the same vacuum transfer vessel and post-processing is performed.

### BACKGROUND OF THE INVENTION

The present invention relates to a vacuum processing apparatus provided with a vacuum vessel inside of which a substrate-like sample such as a semiconductor wafer transferred into a processing chamber is processed in the processing chamber and, particularly, to a vacuum processing apparatus capable of suppressing attachment of contaminating objects to the sample and an operating method of the vacuum processing apparatus.

A vacuum processing apparatus having a plurality of vacuum processing vessels, in which samples such as semiconductor wafers are processed inside processing chambers arranged in the vessels, and transferring and processing one by one of a plurality of the samples sequentially in the processing vessels has been employed in the past in manufacturing of semiconductor devices. One of the most important factors in the performances in such a vacuum processing apparatus has always been to improve processing efficiency and to shorten the processing time of each sample or to improve the number of processed samples per unit time, or so-called “throughput”.

Against such requirements, as for a vacuum processing apparatus according to a related art, a configuration is known in which a transfer means such as a robot arm to transfer the samples is arranged inside a vacuum vessel having a polygonal plane shape to utilize the space inside the vessel as a transfer chamber for sample transfer, and a plurality of vacuum vessels are connected to the side surfaces of the vessel constituting the transfer chamber in such a fashion as to be capable of transferring the sample between the processing chambers therein and the transfer chamber so that the sample is processed in the processing chamber with the processing chamber sealed after one sample is transferred into the chamber. In a so-called “cluster type” apparatus in which a plurality of vacuum processing vessels are connected around one vacuum vessel for transfer (a vacuum transfer vessel), the processings of the samples are executed in parallel in a plurality of vacuum processing vessels and processing efficiency and throughput can therefore be improved in comparison with the apparatus in which a sample is directly transferred to a single vacuum vessel.

Furthermore, as for the cluster type vacuum processing apparatus described above, one in which a portion for processing the sample including the vacuum vessel is configured detachable from the vacuum transfer vessel and constructions necessary for sample processings including the vacuum vessel, a device arranged above for generating an electric or magnetic field, and a vacuum exhaust device arranged below are rendered to be a bundle of a processing unit, has been devised in the past. As for such a processing unit, an etching processing unit for etching a sample and an ashing processing unit for conducting ashing processing by ashing and vaporizing the resist mask consisting principally of resin components, for example, to remove from the surface of a sample have been considered.

Now, when a vacuum processing apparatus is configured with a processing unit for ashing processing as a processing unit, since the ashing processing of the surface of the sample is carried out in vacuum, the sample is generally heated up. As a result of such an ashing processing, when a sample is put at a high temperature so that transfer of the sample may be impeded or the sample may be damaged, as a cluster-type vacuum processing apparatus a processing apparatus is known in which a cooling chamber is connected to the vacuum processing vessel constituting the transfer chamber so that, after transferring the sample taken out from the ashing processing unit executing the ashing processing into the cooling chamber through the transfer chamber and cooling down the sample to a prescribed temperature, it is returned to the atmospheric pressure through a lock chamber connected to the transfer chamber again, as described in JP-A-9-283590.

Also, as a vacuum processing apparatus having a construction different from the cluster type, a vacuum processing apparatus is known as described in JP-A-2002-058985, in which chambers of transfer systems of a load chamber, a first separation chamber (a first vacuum transfer chamber), a substrate heat-treatment chamber (a cooling chamber), and a second separation chamber (a second vacuum transfer chamber) are arranged in this order and a vacuum processing chamber is provided to each separation chamber.

### SUMMARY OF THE INVENTION

In the prior art technologies described above the following points are not sufficiently considered and a problem has been raised. Namely, in the prior art of JP-A-9-283590, extension of the vacuum processing chambers is not considered and reinforcement of the processing capacity per unit area is not sufficiently considered. In other words, there is a problem that extension of the processing chambers is difficult even when an attempt would be made to increase the processing capacity of the cluster-type apparatus.

Also, in the prior art of JP-A-2002-058985, not sufficiently considered is inhibiting compounds formed with products and corrosive gas adhering on a sample during the transfer of the sample from attaching to a sample and becoming contaminating objects, and there is a possibility that in the processing of a sample in the processing chamber further back viewed from the lock chamber, since unprocessed samples pass through a heat-treatment chamber which is an intermediate chamber, adhesive substances attach to the sample to generate contaminating objects. In other words, because the sample is heated up to a high temperature in the substrate heat-treatment chamber, it is in a condition where contaminating objects are likely to be created. Furthermore, even when the chamber is cooled, the contaminating objects are likely to adhere to the surface of the chamber and a problem rises that the products adhering to the surface of the chamber peel off and attach to the sample as contaminating objects to generate contamination of the sample when a sample passes through this chamber as an intermediate chamber.

An objective of the present invention is to provide a vacuum processing apparatus or a method of operating a vacuum processing apparatus, which uses a link system and capable of suppressing attachment of contaminating objects to unprocessed substrates.

The above objective is attained by a vacuum processing apparatus or a method of operating a vacuum processing apparatus which includes: an atmospheric transfer vessel in a space inside of which is at an atmospheric pressure and a wafer to be processed is transferred; a cassette table arranged on a front surface of the atmospheric transfer vessel, onto a top surface of which a cassette capable of accommodating therein a plurality of the wafers is mounted; a lock chamber connected to a back surface side of the atmospheric transfer vessel; a first vacuum transfer vessel arranged at a back of the lock chamber as being connected thereto and comprising a robot which transfers wafers in a depressurized interior thereof; a second vacuum transfer vessel connected at a back of the first vacuum transfer vessel thereto and comprising a robot which transfers wafers in a depressurized interior thereof; processing vessels connected to the first vacuum transfer vessel and the second vacuum transfer vessel, respectively, each of which processes a wafer mounted on a sample stage arranged in a processing chamber in a depressurized interior thereof; post-processing vessels connected to the first vacuum transfer vessel and the second vacuum transfer vessel, respectively, in each of which the wafer processed in one of the processing vessels is transferred and post-processing is executed therein; and an intermediate chamber arranged between the first vacuum transfer vessel and the second vacuum transfer vessel to connect them to communicate interiors thereof and capable of accommodating a wafer, wherein a wafer processed in the processing vessel connected to either of the first vacuum transfer vessel and the second vacuum transfer vessel is transferred to the post-processing vessel connected to a same vacuum transfer vessel and is post-processed.

Further, it is attained by including gate valves arranged between any one of processing chambers in the processing vessels and in the post-processing vessels and the intermediate chamber and a space inside either one of the first vacuum transfer vessel and the second vacuum transfer vessel, and, while one of the gave valves between either one of the first vacuum transfer vessel and the second vacuum transfer vessel and any one of the processing vessels and the post-processing vessels connected thereto is opened, closing the other gate valves between the one of the first vacuum transfer vessel and the second vacuum transfer vessel and the others of the processing vessels, the post-processing vessels, and the intermediate chamber.

Furthermore, it is attained by transferring a wafer processed in a post-processing vessel connected to the second vacuum transfer vessel to the lock chamber after another wafer processed in the processing vessel connected to the first vacuum transfer vessel is transferred to another post-processing vessel connected to the vacuum processing vessel.

Moreover, it is attained by transferring wafers which are planned to be processed in the processing vessel connected to the first vacuum transfer vessel out of the plurality of wafers to either of the processing vessel connected to the first vacuum transfer vessel or a standby chamber connected to the first vacuum processing vessel and accommodating the wafers while waiting for the processing in the processing vessel, or transferring one of the wafers processed in the post-processing vessel connected to the first vacuum transfer vessel to the lock chamber, after wafers which are planned to be processed in the processing vessel connected to the second vacuum transfer vessel are transferred to either of the processing vessel connected to the second vacuum transfer vessel or another standby chamber connected to the second vacuum processing vessel and accommodating the wafers while waiting for the processing in the processing chamber, or after one of the wafers processed in the post-processing vessel connected to the second vacuum transfer vessel is transferred to the lock chamber.

Further, it is attained by each of robot the first vacuum transfer vessel includes and the robot the second vacuum transfer vessel includes being arranged at a center portion of an interior of each of the first vacuum transfer vessel and the second vacuum transfer vessel, being able to change its orientation by rotation with respect to one of the processing vessels, one of the post-processing vessels, the intermediate chamber, or the lock chamber, and having two arms capable of alternately extending and contracting with respect to a same position while supporting and holding the wafer at a distal end thereof.

Furthermore, it is attained by performing an operation in which, when the robot transfers wafers to a target of any one of the vacuum processing vessels, the post-processing vessels, the intermediate chamber, and the lock chamber, after the robot mounts one wafer arranged in the target on an arm and then takes out the wafer on the arm while another arm holds another wafer, the robot transfers the other wafer held by the other arm into the target.

According to the present invention, in a vacuum processing apparatus using a link system in which high temperature processing requiring cooling of the substrate is applied, attachment of contaminating objects onto an unprocessed substrate can be suppressed.

Other objects, features, and advantages of the invention will become apparent from the following description of the embodiments of the invention taken in conjunction with the accompanying drawings.

### BRIEF DESCRIPTION OF THE DRAWINGS

FIG. 1 is a top view schematically showing an outline of a configuration of a vacuum processing apparatus according to an embodiment of the present invention; and

FIG. 2 is a time chart showing the flow of operations of the embodiment shown in FIG. 1.

### DESCRIPTION OF THE EMBODIMENTS

An embodiment of the present invention is explained with reference to the drawings.

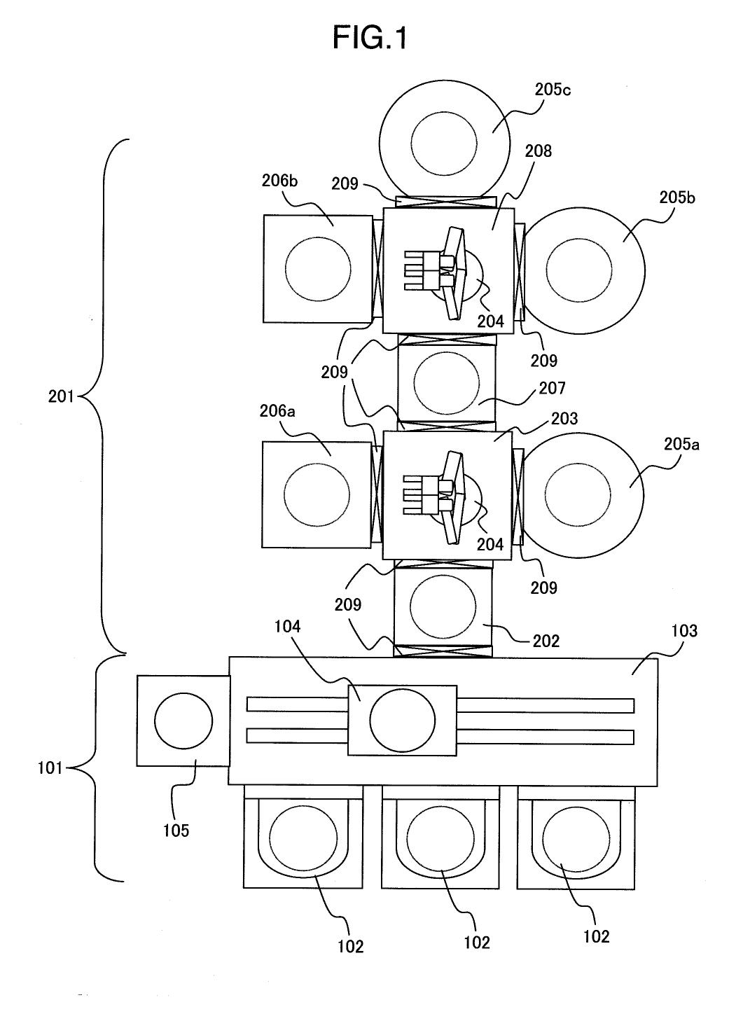

An outline of a configuration of a vacuum processing apparatus according to the present invention is explained with reference to FIG. 1. Incidentally, in the present embodiment, it is explained by way of example of installation of a plurality of ashing units and cooling units.

The vacuum processing apparatus of the present invention can be broadly divided into an atmosphere side block 101 and a vacuum side block 201. The atmosphere side block 101 is the portion where a wafer is transferred, stored, positioned, and the like at an atmospheric pressure and the vacuum side block 201 is the block where a substrate-like sample such as a semiconductor wafer is transferred at a pressure reduced from the atmospheric pressure and ashing processing and cooling processing are carried out.

The vacuum side block 201 further includes a mechanism for making pressure up and down between the atmospheric pressure and the vacuum pressure while the sample is kept therein between a spot of the vacuum side block 201 for executing transfer and processing described above and the atmosphere side block 101.

The atmosphere side block 101 has a casing 103 of a shape of a substantially rectangular parallelepiped having an atmosphere side transfer robot 104 in its interior, and is provided with a plurality of cassette tables 102 attached to the front surface side of the casing 103 on which cassettes storing the wafers therein are mounted and an alignment unit 105 for detecting a notch position of each wafer.

The vacuum side block 201 is the block that is arranged back of the casing 103 and includes a plurality (two in the present embodiment) of vacuum vessels for constituting transfer chambers for transferring the samples in vacuum and a plurality of processing units connected detachably to them. Further, between a first vacuum transfer chamber 203 on the side close to the casing 103 and the atmosphere side block 101, provided is a lock chamber 202 for exchanging the samples between the atmosphere side and the vacuum side and changing the pressure between the atmospheric pressure and the vacuum pressure while it has the samples therein.

The first vacuum transfer chamber 203 is a space (a chamber) for transferring the samples inside a vacuum vessel having a plane shape of a substantially rectangular shape, its interior is depressurized, and a robot for transferring a wafer is arranged in the inside. Further, to the side walls in the lateral direction when the vacuum vessel having the substantially rectangular shape is viewed from above, an ashing unit 205a for executing ashing processing on a wafer and a cooling unit 206a for cooling the wafer subjected to the ashing processing are detachably connected. Furthermore, a vacuum transfer intermediate chamber 207 for exchanging wafers with a second vacuum transfer chamber 208 is connected to the first vacuum transfer chamber 203 further back as viewed from the lock chamber.

Moreover, to the other end (the upper part in the drawing) of the vacuum transfer intermediate chamber 207 a vacuum vessel of a plane shape of a rectangle which constitutes the second vacuum transfer chamber 208 is connected and a gate valve is interposed between each of the first vacuum transfer chamber 203 and the second vacuum transfer chamber 208 and the vacuum transfer intermediate chamber 207 to cut off and open the communication between them as described later so that they are configured to communicate with each other when the gate valves are open. The vacuum vessel constituting the second vacuum transfer chamber 208 also has a plane shape of a substantially rectangular shape and ashing units 205b and 205c and a cooling unit 206b are detachably connected to the side walls constituting the sides of the rectangle.

As described above, the vacuum side block 201 is the block in which a plurality of vacuum vessels that are subjected to depressurization as a whole and are capable of being maintained at a pressure of a high degree of vacuum are detachably connected. Between these vacuum vessels gate valves are interposed to open/close their communications of their interiors so that the inside of each vessel can be cut off from the insides of other vessels and sealed off to make it an independent space.

The inside of each of the first and second vacuum transfer chambers 203 and 208 is a transfer chamber and a vacuum transfer robot 204 is arranged at the center in the transfer chamber for transferring wafers in vacuum among the lock chamber 202, the ashing units 205a, 205b, and 205c, the cooling units 206a and 206b, and the vacuum transfer intermediate chamber 207. The vacuum transfer robot 204, on an arm of which a sample is mounted, performs transfer-in and transfer-out of a sample in the first vacuum transfer chamber 203 with any of sample stages arranged in the ashing unit 205 and the cooling unit 206, the lock chamber 202, and the vacuum transfer intermediate chamber 207.

The robots 204 in the present embodiment have the same construction for the first vacuum transfer chamber 203 and the second vacuum transfer chamber 208 and each has hands configured to be capable of mounting and holding wafers on the distal ends of a plurality (two) of arms. In each arm, a plurality of beam-like members are connected with each other at their both end portions by joint portions and, by turning around axes in the vertical direction arranged at the joint portions to change mutual angles of the interconnected beam-like members the whole length of the arm can be extended and contracted. To each joint portion a driving unit such as a stepping motor that can adjust the angle at high precision is connected.

The hand described above is connected to the beam-like member configuring the tip of one end of each arm, and the tip of the beam-like member at the other end is connected by the joint portion to a plate-like member which rotates around an axis in the vertical direction at the center of the first vacuum transfer chamber 203 or the second vacuum transfer chamber 208 so that the entire arm is configured to be able to rotate around the plate-like member so that the angle can be variably adjusted. Additionally, two arms can change their orientations around their axes by rotations of the plate-like members and make the hand portions of the arms face one of the processing units, the vacuum transfer intermediate chamber 207, or the lock chamber 202, which becomes a target.

In the present embodiment, the two arms rotate as a whole while the hands at their distal end portions are aligned and they are contracted so that the distances from the centers of rotations are minimal, and are positioned to the positions at which they can be extended and contracted facing a target transfer position of a specific processing unit or the like. Under this state, the shapes of respective beam-like members constituting the arms and the adjustments of the rotations of the joint portions are determined in advance lest mutual interference occurs in the arms and the wafers when respective arms are extended and contracted alternately.

Particularly, in the present embodiment, a control unit, not shown in the drawing, adjusts operations to execute an exchange operation so that, while a wafer is mounted and held on the hand of one arm, the other (empty) arm on the hand of which a wafer is not mounted is extended to a target position and to mount a wafer on its hand and contract, and the former arm is then extended to transfer the wafer on the hand to the target position to hand over. By carrying out such the exchange operation, the processing time required for one sample from taking it out from the cassette to returning it to the original position of the cassette after processings can be shortened by reducing the time taking for transfer, and efficiency of processing of the samples and throughput can be improved. In the transfer of the wafers by the robot in the present embodiment, the transfer and the exchange operation of the wafers are carried out principally with the exception of the case where the control unit or a user judges occurrence of abnormality or the first wafer is not accommodated in the processing unit or in the vacuum transfer intermediate chamber 207 (after cleaning or re-start after abnormality).

Between any one of the ashing units 205a, 205b, and 205c, the cooling units 205a and 206b, the lock chamber 202, and the vacuum transfer intermediate chamber 207 and one of the vacuum transfer chambers 203 and 208, all of which are described above, passages are provided to communicate them with one another and the communications of these passages are opened/closed by the gate valves 209 capable of individually opening and closing hermetically. In the vacuum processing apparatus according to the present embodiment, each gate valve 209 executes a so-called “exclusive opening/closing operation”, in which one of these gate valves 209 is opened in the state where the other gate valves connected to the first vacuum transfer chamber 203 or the second vacuum transfer chamber 208 which faces the gate valve 209 are closed. Further, the gate valves 209 arranged in front or back of the vacuum transfer intermediate chamber 207 to open and close the communication between the first vacuum transfer chamber 203 and the second vacuum transfer chamber 208 are controlled by the control unit, not shown in the drawing, lest both are open while wafers are transferred or processed in the vacuum processing apparatus. By this, communication between the first vacuum transfer chamber 203 and the second vacuum transfer chamber 208 is controlled and the interiors of the processing units connected to them respectively are inhibited from being connected spatially through the vacuum transfer intermediate chamber 207 so that movement and contamination of the contaminating objects between the processing units can be mitigated.

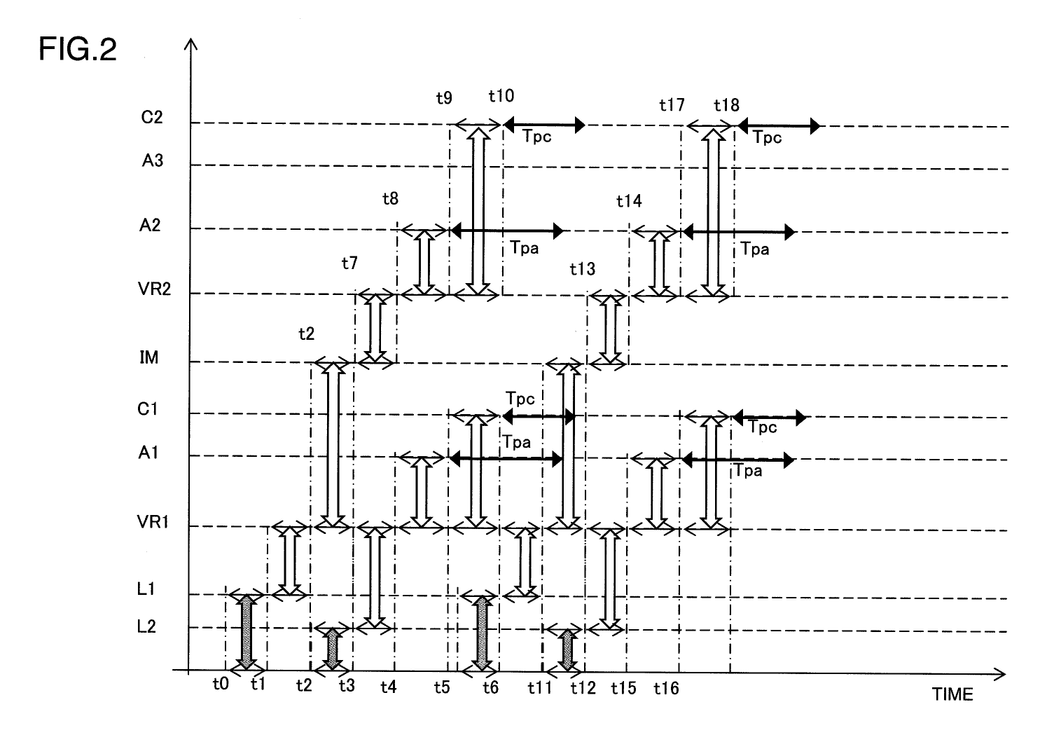

Next, the flow of the operation of wafer processings in the vacuum processing apparatus according to the embodiment shown in FIG. 1 is explained with reference to FIG. 2. FIG. 2 is a time chart showing the flow of the operations in the embodiment shown in FIG. 1.

In the vacuum processing apparatus according to the present embodiment, a wafer is taken out from a cassette table 102 into the inside of the casing 103 by the atmospheric transfer robot 104 in the atmospheric pressure side block 101, transferred to the alignment unit 105 so that the position of the notch formed in advance at a specific position of the outer periphery of the wafer is detected and the angular position of the notch with respect to the wafer center is aligned to a prescribed one, and, thereafter, transferred in by the atmospheric transfer robot 104 into the lock chamber 202 from the alignment unit 105. As for the lock chamber 202 in the present embodiment, even though only one is shown in FIG. 1, two vacuum vessels are arranged with one on top of the other and they are configured so that a plurality of wafers can be accommodated in each.

The atmospheric transfer robot 104 transfers the wafer to either one (L1 or L2) of the two lock chambers 202 on the predetermined transfer route in accordance with the command signal from the control unit not shown in the drawing. In the present embodiment, the gate valve 209 is closed to seal the inside hermetically at the time t0 while the wafer is transferred and accommodated in one (L1) of the lock chambers 202 and depressurization is started to the degree of vacuum similar to that of the first vacuum transfer chamber 203. The gate valve 209 on the vacuum side of L1 is opened at the time t1 and transfer of the wafer to the first vacuum transfer chamber 203 is started.

In this instance, a wafer after processing is held on one of the arms of the robot 204 (hereinafter referred to as “VR1”) in the first vacuum transfer chamber 203 and the exchange operation described above with the wafer before processing in L1 is carried out. In the present drawing, the exchange operation by the robot 204 is represented by a white arrow that connects a broken line representing the operation of VR1 and a broken line representing the operation of the position or the vessel (an ashing unit A1, a cooling unit C1, lock chambers L1, L2, etc) which is a target of the transfer. Incidentally, regarding the exchange operation by the robot 204 in the second vacuum transfer chamber 208, it is represented in the same way as above by a white arrow connecting a broken line of the robot 204 (hereinafter referred to as “VR2”) and a broken line of a target position.

By the operations from the time t1, the wafer transferred from one of the lock chambers L1 into the first vacuum transfer chamber 203 while being held by the robot VR1 is transferred into the vacuum transfer intermediate chamber 207 (hereinafter referred to as “IM”). In other words, the robot VR1 which starts its operation from the time t2 turns its direction to face the vacuum transfer intermediate chamber 207 (IM) while it holds the wafer before processing in one of the arms and the two arms are contracted, and executes the exchange operation with the wafer after processing accommodated in the vacuum transfer intermediate chamber 207 so that the wafer before processing is transferred in the vacuum transfer intermediate chamber 207.

Incidentally, in this instance, among the gate valves 209 which open and close the communications with the first vacuum transfer chamber 203, the gate valves in-between with the lock chamber 202, the ashing unit 205a (hereinafter referred to as “A1”), and the cooling unit 206a (hereinafter referred to as “C1”) are in the closed state and the gate valve 209 between the vacuum transfer intermediate chamber 207 and the first vacuum transfer chamber 203 is in the open state. Furthermore, the gate valve 209 between the vacuum transfer intermediate chamber 207 and the second vacuum transfer chamber 208 is either in the closed state or in the state where they are communicated with a slight spacing so that the movement of particles between them is restricted; it is in the state where communication between the first vacuum transfer chamber 203 and the second vacuum transfer chamber 208 is cut off or the movement of a gas and particles between them is restricted.

The wafer transferred to IM is taken out at the time t7 into the second vacuum transfer intermediate chamber 208 by the robot 204 (VR2). Also, at this time, the exchange operation of the wafer before processing in IM and a wafer after processing held on one of the arms of the robot 204 is started.

After this exchange operation is finished, the operation of transferring the wafer held on VR2 into the ashing unit 205b (hereinafter referred to as “A2”) connected to the second vacuum transfer chamber 208 is started from the time t8. Also, at this time, the exchange operation of VR2 is carried out with a wafer after processing that is processed in the ashing unit 205b (A2).

In the ashing unit A2, ashing processing is started thereafter. In the present embodiment, the wafer held on the sample stage inside the processing chamber that is the internal space of A2 is subjected to the ashing processing at about 300° C. The processing time is Tpa in the present embodiment. The wafer taken out from the ashing unit A2 and held on the robot 204 by the exchange operation is transferred from the time t9 to the cooling unit 206b (hereinafter referred to as “C2”). Also, at this time, the exchange operation of the robot 204 is carried out with a cooled wafer which is already subjected to the processing in the cooling unit C2.

In the cooling unit C2 cooling processing is started thereafter. Namely, while the gate valve 209 partitioning air-tightly with the second vacuum transfer chamber 208 closes its gate and the internal processing chamber is sealed, the wafer is held on the sample stage arranged in the processing chamber with a cooling gas introduced into the processing chamber and is then cooled down for a prescribed period of time, or to the temperature equal to or lower than the value at which no problems would occur for transfer. In the present embodiment, the processing time is Tpc.

After VR1 of the first vacuum transfer chamber 203 transfers the wafer before processing to IM, the operation of taking out another wafer before processing from the other lock chamber 202 (hereinafter referred to as “L2”) and transferring it to the ashing unit 205a (hereinafter referred to as “A1”) connected to the first vacuum transfer chamber 203 is carried out from the time t3. From the time t3 immediately after the transfer to IM executed from the time t2 is completed, the operation of transferring the wafer before processing accommodated in L2 at a reduced pressure into the first vacuum transfer chamber 203 by VR1 is carried out. The time t3 and the time t7 coincide in FIG. 2 but it is not limited thereto.

The transfer operation of the wafer by VR1 into the first vacuum transfer chamber 203 that is executed from the time t3 is carried out by the exchange operation of the wafer after processing held beforehand on one of the arms of VR1 in advance (the one moved from IM onto VR1 by the exchange operation of the wafers in the IM and VR1 from the time t2) and the wafer before processing in L2 in the same way as described above. In the present drawing it is shown that this exchange operation of VR1 is executed in the same time as the exchange operation of the wafers between VR2 and IM executed from the time t7; this is because the configurations such as the construction and the control method are the same between VR1 and VR2 and the wafer support structure of L2 and the wafer support structure of IM are substantially the same and, therefore, the operation procedures and the times of VR1 and VR2 actually become equivalent between them, and the invention associated with the present embodiment is not limited thereto.

Due to the exchange operation of VR1 from the time t3 the wafer before processing held on VR1 in the first vacuum transfer chamber 203 is transferred to the ashing unit (A1) by operation of VR1 from the time t4. Also in this operation, the wafer exchange operation is carried out between VR1 and A1. Incidentally, in the present drawing, the time required for this exchange operation is equivalent to that for the exchange operation between VR2 and A2 executed from the time t8.

After the transfer of the wafer before processing into A1 by VR1 is completed and the inside of A1 is hermetically partitioned from the interior of the first vacuum transfer chamber 203 by the closing operation of the gate valve 209, the ashing processing is started. In the present embodiment, the wafer held on the sample stage in the processing chamber is subjected to ashing processing at about 300° C. for the time Tpa in the same way as A2.

A wafer finished with ashing processing held on VR1 due to the exchange operation of VR1 from the time t4 is transferred to the cooling unit 206a (hereinafter referred to as “C1”) by the operation of VR1 from the time t5. Also, at this time, the wafer exchange operation is carried out between VR1 and C1.

After the transfer of the wafer after ashing processing to C1 is completed, the cooling processing of the wafer is carried out in C1. In the present embodiment, the cooling processing in C1 is carried out during the same time Tpc as C2.

In the present embodiment, once the exchange operation of the wafer between VR1 and C1 (transfer of the wafer after ashing processing to C1) is completed, no necessary operation of VR1 exists in principle until a wafer before processing is accommodated in at least either one of the lock chambers 202 and evacuation is finished to a prescribed degree of vacuum. Therefore, when a wafer before processing is accommodated in any one of the lock chambers 202 and evacuation is completed before the completion of the exchange operation between VR1 and C1 from the time t5, transfer of the wafer before processing by VR1 into the first vacuum transfer chamber 203 can be started immediately so that the waste time can be reduced and the time required for processing per wafer can be shortened to improve throughput.

In the embodiment of the present drawing, L1 accommodates the wafer before processing and finishes with depressurization by an adjustment from the control unit before the completion of the exchange operation from the time t5. Incidentally, in the drawing, such depressurization operation with wafers before processing being accommodated in L1 or L2 is represented by a hatched arrow connecting the axis of abscissa and a broken line representing the operations of L1 or L2.

The exchange operation of the wafers by VR1 for L1 is started from the time t6 immediately after the completion of the exchange operation in accordance with a command from the control unit, not shown in the drawing. Namely, after VR1 is turned so that its orientation is made to face the gate on the side of the first vacuum transfer chamber 203 of L1 and the gate valve 209 hermetically partitioning the gate is opened, the transfer is started. The subsequent operations are analogous to the operation started from the time t11, t12, t13, or the like after the time t1.

After the wafer after cooling processing held on one of the arms by the exchange operation of VR1 is transferred to either one of the lock chambers 202, the pressure inside the lock chamber 202 is raised to the atmospheric pressure or the pressure approximate to what can be regarded as it, the gate valve partitioning the inside of the atmospheric transfer chamber inside the casing 103 and the lock chamber 202 is then opened, and the wafer is transferred out from the inside of the lock chamber 202 by the atmospheric transfer robot 104 and is accommodated at the original position of the original cassette on the cassette table 102, thereby finishing the processings of the wafer.

Incidentally, in the present embodiment, the time Tpa of the ashing processing executed in the ashing units 205a, 205b, and 205c and the time Tpc of the cooling processing executed in the cooling units 206a and 206b are common in the same processing units, respectively, but the present invention is not limited thereto. Also, the time Tpa is made shorter than the time from the time t4 to the end point of the wafer exchange operation or the time from the time t5 to the time t15. Therefore, since the ashing processing in A1 is finished before the finish of the wafer exchange operation between L2 and VR1 started from the time t12, the wafer exchange operation between VR1 and A1 can be immediately started from the time t15 immediately after the finish of the exchange operation.

Similarly, the time Tpa is made shorter than the time between the end point (or the time t9, specifically) of the wafer exchange operation between VR2 and A2 started from the time t8 and the end point (or the time t14, specifically) of the wafer exchange operation between IM and VR2 started from the time t13. Furthermore, the time Tpc is made shorter than time between the time t10 and the end point of the wafer exchange operation between VR2 and A2 started from the time t14. Consequently, the waiting time in the processing unit until the start of the processing is reduced and processing efficiency is improved. This also holds true of the ashing processing of A2 started from the time t17 and the cooling processing of C2 started from the time t18.

In the embodiment shown in FIG. 2 described above an example in which ashing processings are performed using only the ashing unit 205b connected to the second vacuum transfer chamber 208 is shown but the invention associated with the present embodiment is not limited thereto and the ashing processing unit 205c may well be used in parallel with the ashing unit 205b. In the present embodiment, wafers finished with ashing processing in the ashing unit 205a, 205b, and 205c are, thereafter, transferred to either the cooling unit 206a commonly connected to the first vacuum transfer chamber 203 or the cooling unit 206b commonly connected to the second vacuum transfer chamber 208 through the above common vacuum transfer chamber and are subjected to the cooling processing.

In other words, in the present embodiment, the wafers after ashing processing but before cooling processing are not transferred through different vacuum transfer chambers but are transferred through a partitioned single vacuum transfer chamber or a partitioned space for vacuum transfer. Further, the vacuum processing apparatus according to the present embodiment is configured so that a user can select a run of such operations as a run mode.

In these runs, as for each of a plurality of unprocessed wafers accommodated in the cassette, before it is transferred into the vacuum side block 201, or more specifically, before positioning is conducted in the alignment unit 105, a wafer transfer route is set as one of the run parameters in addition to so-called “recipe” such as a processing unit for executing processing and processing conditions (gas species, time, pressure inside the processing chamber, etc). Namely, the vacuum processing apparatus is adjusted for its run to be implemented based on the specific run conditions and configured to be able to realize its run by setting or selecting runs, in which adjustments and controls are different for different conditions of the run conditions.

More specifically, the run parameters set as the run conditions include a transfer route of each wafer, a transfer sequence of a plurality of wafers, and the conditions of the above-mentioned processings in the processing units to which the wafers are transferred. These parameters, which are set in advance for each wafer, have patterns of run parameters common or different for a group of a plurality of wafers or patterns constituted by the repetition of run parameters common to a group of a plurality of wafers and different for each of different groups.

The vacuum processing apparatus according to the present embodiment is configured so that a user can select and set run conditions which include these common parameters or each of the patterns of the parameters as run parameters as a run mode. The vacuum processing apparatus includes a display means such as a monitor, not shown in the drawing, and is configured so that an arbitrary one can be selected on the display means from a plurality of run modes displayed on the display means. For example, a plurality of run modes having mutually different transfer routes of wafers are displayed on a liquid crystal monitor and a user can select one mode on the monitor with designation means such as a mouse, a keyboard, or a touch panel.

The control unit of the vacuum processing apparatus is connected to the designation means or the monitor in a way of enabling to communicate and a result of designation of the run mode is transmitted to an internal computing element through an interface arranged inside the control unit. The computing element sets the transfer route and the transfer sequence for each of a plurality of wafers in accordance with the common parameters or the patterns of the parameters prescribed in the designated run mode, and regulates the run of the vacuum processing apparatus based on them. The run modes and the run parameters and the patterns of the parameters corresponding to them are stored in advance as data inside the control unit or in a storage device such as a hard disk or a memory at a different location connected to be capable of communication with it; the computing element of the control unit reads out the data in the storage device in accordance with the designated run mode to calculate or select the values of the run parameters and sends command signals for implementing it to each part of the vacuum processing apparatus to regulate the operations.

In a transfer route of a wafer as a run parameter, the positions (hereinafter referred to as “stations”) at which the wafer is held and stays for at least an arbitrary time after it is taken out from a cassette and returned after processing, including the cassette, the alignment unit 105, the lock chamber 202, the first vacuum transfer chamber 203, the robot 204, the vacuum transfer intermediate chamber 207, the second vacuum transfer chamber 208, the ashing units 205a, 205b, and 205c, and the cooling units 206a and 206b and the retention time at these stations are also included. In other words, as one transfer route, from a cassette through the alignment unit 105 to either L1 or L2 of the lock chamber 202, further from either L1 or L2 to either the vacuum transfer intermediate chamber 207 or the ashing unit 205a by the robot 204 (VR1) of the first vacuum transfer chamber 203, through the cooling unit 206a (C1) to either L1 or L2 of the lock chamber 202 when it is transferred to the ashing unit 205a, and to either one of the ashing processing units 205b and 205c by VR2 when it is transferred to the vacuum transfer intermediate chamber 207 and further through the cooling unit 206b and the vacuum transfer intermediate chamber 207 to either L1 or L2 of the lock chamber 202 is selected and set.

Further, the retention time at each station is set by adding the time required for the operation on a wafer at each station and a time for delay of a prescribed operation before or after it; when the actual retention time exceeds the set retention time or its tolerance time, the control unit judges whether or not if any abnormality exists; when it is judged to be an abnormality, a user is notified of it and it is switched over to a predetermined run condition or run mode. In this switching over change of the run condition such as to a different run mode or to the one of the same pattern of the run parameters with different values of parameters from before is executed. Such a change of the run conditions includes a change from the exchange operation of the wafers by the robot 204 to only either transfer-in or transfer-out.

In the above-described embodiment two vacuum transfer chambers are used; the invention associated with the present embodiment can also be applied when three or more vacuum transfer chambers are connected through vacuum transfer intermediate chambers 207, respectively. Also, in this case, the vacuum processing apparatus is operated in a run mode where a wafer processed in an ashing unit connected to an individual vacuum transfer chamber is transferred into a cooling unit connected to the vacuum transfer chamber through only the vacuum transfer chamber and cooled there, respectively, and an operation in which a wafer is transferred to another vacuum transfer chamber and to a cooling unit connected to the vacuum transfer chamber through a vacuum transfer intermediate chamber 207 is not carried out with an exception of a specific case such as when an abnormality occurs.

Further, when three or more vacuum transfer chambers are interconnected through vacuum transfer intermediate chambers 207, in the same way as in the example shown in FIG. 2, wafers before processing are first transferred to the vacuum transfer chamber furthest back from the lock chamber 202 as viewed from the front and to an ashing unit connected thereto, and wafers before processing are then transferred to vacuum transfer chambers further back and to ashing units connected thereto subsequently. Moreover, it is similar to the embodiment of FIGS. 1 and 2 that transfer of wafers to target positions by the robots 204 are carried out primarily by the exchange operation.

Furthermore, in a vacuum processing apparatus having three or more vacuum transfer chambers, the run conditions of the vacuum processing apparatus are set so that the number of wafers to be processed in processing units connected to individual vacuum transfer chambers arranged third or further back from the lock chamber 202 is greater than the number of wafers processed in processing units connected to individual vacuum transfer chambers back by up to two from the lock chamber 202 in a group of a prescribed number of wafers as one lot. In other words, when a vacuum transfer chamber and processing units connected thereto are regarded as one processing block, the number of wafers processed in individual processing blocks arranged third or further back counted from the lock chamber 202 is made to be a greater value than the number of wafers processed in individual processing blocks closer to the lock chamber than those. However, the number of wafers processed in the processing block furthest back is made smaller than the sum of the numbers of wafers processed in the processing blocks closer (more toward the front) to the lock chamber 202.

Additionally, in a vacuum processing apparatus having three or more vacuum transfer chambers, instead of transferring wafers before processing to each processing block one by one, a plurality of wafers may be transferred successively to a specific processing block. In particular, by transferring two or more wafers successively to the processing blocks arranged third or further back viewed from the lock chamber 202, processing efficiency of the entire vacuum processing apparatus can be improved and, hence, the throughput can be improved. Also, standby stations each having a vessel for accommodating the plurality of wafers after they are transferred to the processing block until they are transferred into the processing units of the processing block for processing may be connected to a vacuum vessel constituting the vacuum transfer chamber of the processing block to be arranged to be communicated with the vacuum transfer chamber. Further, in such a standby station, it may be configured to be able to accommodate wafers after processing.

In such a case, after start of one lot, a plurality of wafers before processing are transferred to the furthest back processing block and a designated number of wafers before processing are then transferred to processing blocks further back from the lock chamber 202 successively to start the processings. Besides, timings of starts of processings of the wafers before processing in individual processing blocks need not be synchronized; because at least any of the gate valves 209 arranged at the front or rear end portions of the vacuum transfer intermediate chambers 207 are closed hermitically or with a smaller gap so that movement of particles is restricted, the ashing processing and the cooling processing of unprocessed wafers are started and the wafers after processing are recovered independently in each processing block. Therefore, deterioration of throughput is inhibited and decrease of processing efficiency of the entire vacuum processing apparatus can be suppressed.

Also, in this case, transfer of wafers to the processing block at the second furthest is executed after transfer of wafers to the furthest back processing block is completed, in the same way as in the embodiment shown in FIGS. 1 and 2. Further, such a wafer transfer is performed by the exchange operation in which transfer-in of wafers before processing into an arbitrary processing block and transfer-out (return) of wafers after processing to the lock chamber 202 are alternately carried out. Therefore, a plurality of wafers processed in different processing blocks are inhibited from being returned back and forth as mixed so that generation of contamination across the wafers can be suppressed and tracking and clarification of the causes become easy when contaminating objects are created.

In the embodiment described above, wafers of high temperature after ashing processing are not transferred into the vacuum transfer intermediate chamber 207, and, therefore, contamination of the vacuum transfer intermediate chamber 207 can be reduced and attachment of contaminating objects to wafers before processing passing through the vacuum transfer intermediate chamber 207 can be suppressed or avoided. Besides, even when the contaminating objects are generated on the wafers, examination and clarification of the causes become easy because, when the causes of the contaminating objects are presumed within transfer routes, transfer routes are limited to specific ones constructed by different vacuum transfer chambers interposing vacuum transfer intermediate chambers 207 between them and processing units connected to them, respectively.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus comprising:
an atmospheric transfer vessel in a space inside of which is at an atmospheric pressure and a wafer to be processed is transferred;
a cassette table arranged on a front surface of the atmospheric transfer vessel, onto a top surface of which a cassette capable of accommodating therein a plurality of the wafers is mounted;
a lock chamber connected to a back surface side of the atmospheric transfer vessel;
a first vacuum transfer vessel arranged at a back of the lock chamber as being connected thereto and comprising a robot which transfers wafers in a depressurized interior thereof;
a second vacuum transfer vessel connected at a back of the first vacuum transfer vessel thereto and comprising a robot which transfers wafers in a depressurized interior thereof;
processing vessels connected to the first vacuum transfer vessel and the second vacuum transfer vessel, respectively, each of which processes a wafer mounted on a sample stage arranged in a processing chamber in a depressurized interior thereof;
post-processing vessels connected to the first vacuum transfer vessel and the second vacuum transfer vessel, respectively, in each of which the wafer processed in one of the processing vessels is transferred and post-processing is executed therein; and
an intermediate chamber arranged between the first vacuum transfer vessel and the second vacuum transfer vessel to connect them to communicate interiors thereof and capable of accommodating a wafer,
wherein a wafer processed in the processing vessel connected to either of the first vacuum transfer vessel and the second vacuum transfer vessel is transferred to the post-processing vessel connected to a same vacuum transfer vessel and is post-processed.

2. The vacuum processing apparatus according to claim 1, further comprising gate valves arranged between any one of processing chambers in the processing vessels and in the post-processing vessels and the intermediate chamber and a space inside either one of the first vacuum transfer vessel and the second vacuum transfer vessel, wherein, while one of the gave valves between either one of the first vacuum transfer vessel and the second vacuum transfer vessel and any one of the processing vessels and the post-processing vessels connected thereto is opened, the other gate valves between the one of the first vacuum transfer vessel and the second vacuum transfer vessel and the others of the processing vessels, the post-processing vessels, and the intermediate chamber are closed.

3. The vacuum processing apparatus according to claim 1, wherein a wafer processed in a post-processing vessel connected to the second vacuum transfer vessel is transferred to the lock chamber after another wafer processed in the processing vessel connected to the first vacuum transfer vessel is transferred to another post-processing vessel connected to the vacuum processing vessel.

4. The vacuum processing apparatus according to claim 1, wherein wafers which are planned to be processed in the processing vessel connected to the first vacuum transfer vessel out of the plurality of the wafers are transferred to either of the processing vessel connected to the first vacuum transfer vessel or a standby chamber connected to the first vacuum processing vessel and accommodating the wafers while waiting for the processing in the processing chamber, or one of the wafers processed in the post-processing vessel connected to the first vacuum transfer vessel is transferred to the lock chamber, after wafers which are planned to be processed in the processing vessel connected to the second vacuum transfer vessel are transferred to either of the processing vessel connected to the second vacuum transfer vessel or another standby chamber connected to the second vacuum processing vessel and accommodating the wafers while waiting for the processing in the processing chamber, or after one of the wafers processed in the post-processing vessel connected to the second vacuum transfer vessel is transferred to the lock chamber.

5. The vacuum processing apparatus according to claim 4, wherein each of the robot the first vacuum transfer vessel comprises and the robot the second vacuum transfer vessel comprises is arranged at a center portion of an interior of each of the first vacuum transfer vessel and the second vacuum transfer vessel, is able to change its orientation by rotation with respect to one of the processing vessels, one of the post-processing vessels, the intermediate chamber, or the lock chamber, and has two arms capable of alternately extending and contracting with respect to a same position while supporting and holding the wafer at a distal end thereof.

6. The vacuum processing apparatus according to claim 5, wherein, when the robot transfers wafers to a target of any one of the vacuum processing vessels, the post-processing vessels, the intermediate chamber, and the lock chamber, after the robot mounts one wafer arranged in the target on an arm and then takes out the wafer on the arm while another arm holds another wafer, the robot transfers the other wafer held by the other arm into the target.

7. A method of operating a vacuum processing apparatus which comprises;
an atmospheric transfer vessel in a space inside of which is at an atmospheric pressure and a wafer to be processed is transferred;
a cassette table arranged on a front surface of the atmospheric transfer vessel, onto a top surface of which a cassette capable of accommodating therein a plurality of the wafers is mounted;
a lock chamber connected to a back surface side of the atmospheric transfer vessel;
a first vacuum transfer vessel arranged at a back of the lock chamber as being connected thereto and comprising a robot which transfers wafers in a depressurized interior thereof;
a second vacuum transfer vessel connected at a back of the first vacuum transfer vessel thereto and comprising a robot which transfers wafers in a depressurized interior thereof;
processing vessels connected to the first vacuum transfer vessel and the second vacuum transfer vessel, respectively, each of which processes a wafer mounted on a sample stage arranged in a processing chamber in a depressurized interior thereof;
post-processing vessels connected to the first vacuum transfer vessel and the second vacuum transfer vessel, respectively, in each of which the wafer processed in one of the processing vessels is transferred and post-processing is executed therein; and
an intermediate chamber arranged between the first vacuum transfer vessel and the second vacuum transfer vessel to connect them to communicate interiors thereof and capable of accommodating a wafer, the method comprising the steps of:
processing a wafer in the processing vessel connected to either of the first vacuum transfer vessel and the second vacuum transfer vessel;
transferring the wafer to the post-processing vessel connected to a same vacuum transfer vessel; and
post-processing the wafer.

8. The method of operating a vacuum processing apparatus according to claim 7, wherein the vacuum processing apparatus further comprises gate valves arranged between any one of processing chambers in the processing vessels and in the post-processing vessels and the intermediate chamber and a space inside either one of the first vacuum transfer vessel and the second vacuum transfer vessel, wherein, while one of the gate valves between either one of the first vacuum transfer vessel and the second vacuum transfer vessel and any one of the processing vessels and the post-processing vessels connected thereto is opened, the other gate valves between the one of the first vacuum transfer vessel and the second vacuum transfer vessel and the others of the processing vessels, the post-processing vessels, and the intermediate chamber are closed.

9. The method of operating a vacuum processing apparatus according to claim 7, further comprising the step of: transferring a wafer processed in a post-processing vessel connected to the second vacuum transfer vessel to the lock chamber after another wafer processed in the processing vessel connected to the first vacuum transfer vessel is transferred to another post-processing vessel connected to the vacuum processing vessel.

10. The method of operating a vacuum processing apparatus according to claim 7, further comprising the step of: transferring wafers which are planned to be processed in the processing vessel connected to the first vacuum transfer vessel our of the plurality of the wafers are transferred to either of the processing vessel connected to the first vacuum transfer vessel or a standby chamber connected to the first vacuum processing vessel and accommodating the wafers while waiting for the processing in the processing chamber, or transferring one of the wafers processed in the post-processing vessel connected to the first vacuum transfer vessel to the lock chamber, after wafers which are planned to be processed in the processing vessel connected to the second vacuum transfer vessel are transferred to either of the processing vessel connected to the second vacuum transfer vessel or another standby chamber connected to the second vacuum processing vessel and accommodating the wafers while waiting for the processing in the processing chamber, or after one of the wafers processed in the post-processing vessel connected to the second vacuum transfer vessel is transferred to the lock chamber.
